(19) United States
(12) Patent Application Publication
(10) Pub. No.: US 2014/0224311 A1
(43) Pub. Date: Aug. 14, 2014

(54) PHOTOELECTRIC CONVERSION ELEMENT, METHOD OF MANUFACTURING SAME, AND PHOTOELECTRIC CONVERSION DEVICE

(71) Applicants: Shinichi Abe, Uji-shi (JP); Hirotaka Sano, Omihachiman-shi (JP); Shuichi Kasai, Kagoshima-shi (JP)

(72) Inventors: Shinichi Abe, Uji-shi (JP); Hirotaka Sano, Omihachiman-shi (JP); Shuichi Kasai, Kagoshima-shi (JP)

(73) Assignee: KYOCERA CORPORATION, Kyoto-shi, Kyoto (JP)

(21) Appl. No.: 14/342,233

(22) PCT Filed: Aug. 29, 2012
(86) PCT No.: PCT/JP2012/071860

§ 371 Date: Feb. 28, 2014

(30) Foreign Application Priority Data
Aug. 30, 2011 (JP) 2011-187046

(51) Int. Cl. H01L 31/032; H01L 31/18

(52) U.S. Cl. CPC H01L 31/0322; H01L 31/18
USPC 136/255; 438/95

(57) ABSTRACT

A photoelectric conversion element, a photoelectric conversion device and a method for manufacturing a photoelectric conversion element are disclosed. The photoelectric conversion element includes a lower electrode layer, a light absorption layer on the lower electrode layer and a semiconductor layer on the light absorption layer. The light absorption layer includes a group I-III-VI compound containing a group I-B element, a group III-B element, and Se. The semiconductor layer includes a group III-VI compound containing a group III-B element, S, and Se. The composition in atomic percent of Se of the group III-VI compound of the semiconductor layer at a side of the light absorption layer is higher than that at a side opposite to the light absorption layer. The photoelectric conversion device includes the aforementioned photoelectric conversion element.

### TECHNICAL FIELD

The present invention relates to a photoelectric conversion element, a method for manufacturing the same, and a photoelectric conversion device.

### BACKGROUND ART

Heretofore, a photoelectric conversion device is formed in such a way that photoelectric conversion elements, each of which functions as a constituent unit and includes a light absorption layer formed, for example, of chalcopyrite-based CIGS, are connected in series or in parallel on a substrate, such as a glass.

In this photoelectric conversion device, at a light receiving surface side thereof, that is, on the light absorption layer, a buffer layer is provided.

In order to obtain a preferable hetero-junction with the light absorption layer, this buffer layer is chemically grown from a solution by a chemical bath deposition method (CBD method) or the like.

However, for example, in a composition structure of a common CIGS-based light absorption layer and an In₂S₃-based buffer layer, as shown in FIG. 4(a), the bandgap is still small due to a negative band offset ΔEc2, and hence, the photoelectric conversion efficiency may not be sufficiently satisfied in some cases.

In addition, it has been known that when an A layer formed of a compound containing Se and at least one selected from Zn and In is provided between a p-type first semiconductor layer (light absorption layer) and an n-type second semiconductor layer (window layer), the first semiconductor layer is prevented from being damaged when the second semiconductor layer is formed on the first semiconductor layer by sputtering (see PTL 1).

Alternatively, it has also been known that a semiconductor layer formed of a group I-B element, a group III-B element, and a VI-B element and containing at least one minor element is formed on a surface of a semiconductor thin film formed of a group I-B element, a group III-B element, and a VI-B element (see PTL 2).

In addition, it has also been known that a surface of a CIGS-based light absorption layer is modified by doping of S at a surface side thereof (light absorption surface side) (see PTL 3).

### CITATION LIST

### Patent Literature

PTL 1: Japanese Unexamined Patent Application Publication No. 2002-124688

PTL 2: Japanese Unexamined Patent Application Publication No. 10-341029

PTL 3: Japanese Unexamined Patent Application Publication No. 8-330614

### SUMMARY OF INVENTION

### Technical Problem

However, in the photoelectric conversion device disclosed in PTL 1, since the A layer which is different from the first semiconductor layer and the second semiconductor layer is additionally provided, the band discontinuity is liable to be generated, and as a result, the photoelectric conversion efficiency was decreased in some cases.

In addition, in the photoelectric conversion device disclosed in PTL 2, since the semiconductor layer containing a group I-B element (Cu in this case) is essentially formed on the surface of the semiconductor thin film, a leakage current was liable to be generated in some cases.

In addition, in the photoelectric conversion device disclosed in PTL 3, since a large amount of oxygen is also mixed in the interface between the light absorption layer and the buffer layer, a preferable pn junction is damaged, and as a result, the photoelectric conversion efficiency was decreased in some cases.

### Solution to Problem

A photoelectric conversion element according to the present invention includes: a light absorption layer which is provided on a lower electrode layer and which is composed of a group I-III-VI compound containing a group I-B element, a group III-B element, and Se; and a semiconductor layer which is provided on the light absorption layer and which is composed of a group III-VI compound containing a group III-B element, S, and Se, and the composition (atomic percent) of Se of the group III-VI compound of the semiconductor layer at a side of the light absorption layer is higher than that at a side opposite to the light absorption layer.

In addition, a method for manufacturing a photoelectric conversion element according to the present invention includes: immersing a light absorption layer composed of a group I-III-VI compound containing a group I-B element, a group III-B element, and Se in a film forming solution containing a group III-B element, S, and Se; and forming a semiconductor layer composed of a group III-VI compound thereon by making the ratio of Se to S in the film forming solution lower.

In addition, a photoelectric conversion device according to the present invention uses the photoelectric conversion element described above.

### Advantageous Effects of Invention

According to the photoelectric conversion element of the present invention, since a Se compound containing a group III-B element, which has a band offset larger than that of a sulfide containing a group III-B element, is contained in a larger amount at the light absorption layer side of the semiconductor layer, a negative band offset ΔEc2 at the interface between the light absorption layer and the semiconductor layer can be changed to a positive band offset ΔEc1, and at the same time, the valence band level at the interface can also be decreased.

Accordingly, carrier recombination caused by crystalline defects is suppressed, and hence, the photoelectric conversion efficiency can be improved.

### BRIEF DESCRIPTION OF DRAWINGS

FIG. 1 is a schematic view of a photoelectric conversion element according to this embodiment.

FIG. 2 is a schematic view of a photoelectric conversion device according to this embodiment.

FIG. 3 is a graph showing a composition distribution of a light absorption layer and that of a semiconductor layer of the photoelectric conversion element according to this embodiment.

FIG. 4 includes graphs each showing the relationship between the band offset (lower column) and the composition distribution (upper column) of Se in the light absorption layer and the semiconductor layer of the photoelectric conversion element according to this embodiment, (a) indicates the case of a related example, and (b) indicates the case according to one embodiment of the present invention.

FIG. 5 is a graph showing the relationship between the photoelectric conversion efficiency and the ratio of Se in the semiconductor layer of the photoelectric conversion element according to this embodiment.

FIG. 6 is a photo of the light absorption layer and the semiconductor layer of the photoelectric conversion element according to this embodiment.

FIG. 7 is a graph showing the composition distribution of a light absorption layer and that of a semiconductor layer of a related photoelectric conversion element.

FIG. 8 is a ternary phase diagram of a Cu—In—Se-based compound used for the semiconductor layer of the photoelectric conversion element according to this embodiment.

### DESCRIPTION OF EMBODIMENTS

Hereinafter, a photoelectric conversion element, a method for manufacturing the same, and a photoelectric conversion device according to embodiments of the present invention will be described in detail with reference to the drawings.

### Photoelectric Conversion Element

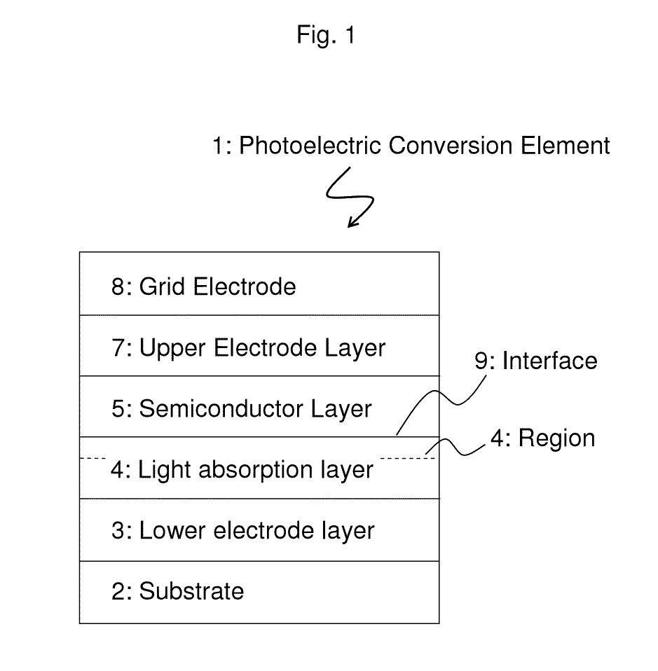

As shown in FIG. 1, a photoelectric conversion element 1 includes a substrate 2, a lower electrode layer 3, a light absorption layer 4, a semiconductor layer 5, an upper electrode layer 7, and a grid electrode 8.

The substrate 2 is configured to support the photoelectric conversion element 1. As a material used for the substrate 2, for example, a glass, a ceramic, a resin, and a metal may be mentioned.

The lower electrode layer 3 is formed on the substrate 2 from a conductive material, such as Mo, Al, Ti, or Au, by a sputtering method, a deposition method, or the like.

The light absorption layer 4 preferably contains a chalcopyrite-based material and has a function to generate a charge by absorption of light. Although the light absorption layer 4 is not particularly limited, in consideration that even a thin layer having a thickness of 10 μm or less can obtain a high photoelectric conversion efficiency, a chalcopyrite-based compound semiconductor is preferable.

As the chalcopyrite-based compound semiconductor according to this embodiment, a group I-III-VI compound containing a group I-B element, a group III-B element, and Se, such as Cu(In,Ga)Se₂ (also referred to as CIGS) or Cu(In,Ga)(Se,S)₂ (also referred to as CIGSS), may be mentioned.

In addition, Cu(In,Ga)Se₂ indicates a compound primarily formed from Cu, In, Ga, and Se. In addition, Cu(In,Ga)(Se,S)₂ indicates a compound primarily formed from Cu, In, Ga, Se, and S.

The light absorption layer 3 as described above may be formed by the following method.

First, raw material elements (such as a group I-B element, a group III-B element, and a group VI-B element) are formed into a film by sputtering or deposition, or a raw material solution is formed into a film by application, so that a precursor containing the raw material elements is formed.

Subsequently, by heating this precursor, the light absorption layer 4 of a compound semiconductor can be formed. Alternatively, the light absorption layer 4 may also be formed in such a way that as in the case described above, after metal elements (such as a group I-B element and a group III-B element) are formed into a film as the precursor, this precursor is heated in a gas atmosphere containing a group VI-B element.

The semiconductor layer 5 indicates a layer which forms a hetero-junction with the light absorption layer 4. The semiconductor layer 5 is formed on the light absorption layer 4 to have a thickness of approximately 5 to 200 nm.

The semiconductor layer 5 preferably has a conductive type different from that of the light absorption layer 4, and for example, when the light absorption layer 4 is a p-type semiconductor, the semiconductor layer 5 is an n-type semiconductor.

In order to reduce a leakage current, the semiconductor layer 5 preferably has a resistivity of 1 Ω/cm or more. In addition, in order to increase a light absorption efficiency of the light absorption layer 4, the semiconductor layer 5 preferably has an optical transparency with respect to a wavelength region of light which is absorbed by the light absorption layer 4.

The semiconductor layer 5 as described above is formed by a wet film forming method. As the wet film forming method, for example, there may be mentioned a method in which after a raw material solution is applied on the light absorption layer 4, a chemical reaction is performed in the applied solution by a treatment, such as heating, or a method in which by a chemical reaction performed in a solution containing raw materials, the semiconductor layer 5 is deposited on the light absorption layer 4.

By the methods as described above, the semiconductor layer 5 is formed so as to diffuse to a light absorption layer 4 side to a certain extent, and as a result, the hetero-junction between the light absorption layer 4 and the semiconductor layer 5 may be preferably formed to have a small number of defects.

The upper electrode layer 7 is a layer which has a resistivity lower than that of the semiconductor layer 5 and which functions to extract a charge generated in the light absorption layer 4.

In order to efficiently extract a charge, the upper electrode layer 7 preferably has a resistivity of less than 1 Ω/cm and a sheet resistance of 500Ω/□ or less.

In addition, in order to increase the absorption efficiency of the light absorption layer 4, the upper electrode layer 5 preferably has an optical transparency with respect to light which is absorbed by the light absorption layer 4.

In addition, besides the increase in optical transparency, in order to enhance an effect of reducing an optical loss caused by reflection and an effect of scattering light and, furthermore, in order to preferably conduct a current generated by the photoelectric conversion, the upper electrode layer 7 preferably has a thickness of 0.05 to 0.5 μm.

In addition, in order to reduce the optical loss caused by reflection at the interface between the upper electrode layer 7 and the semiconductor layer 5, the refractive index of the upper electrode layer 7 is preferably approximately equivalent to that of the semiconductor layer 5.

As the upper electrode layer 7 described above, a transparent conductive film formed of ITO or ZnO and having a thickness of 0.05 to 3 μm is preferable and is formed, for example, by a sputtering method, a deposition method, or a chemical vapor deposition (CVD) method.

### Photoelectric Conversion Device

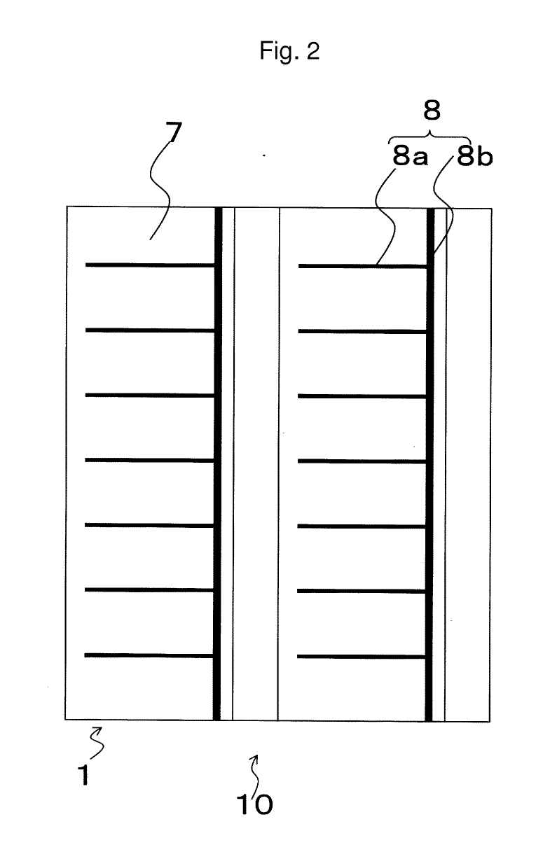

In FIG. 2, in a photoelectric conversion device 10, a plurality of the photoelectric conversion elements 1 are arranged, and adjacent photoelectric conversion elements 1 are connected to each other in series by connection conductors (not shown).

In addition, on the upper electrode layer 7, a collector electrode 8 formed of finger electrodes 8a and a bus bar electrode 8b is provided.

The photoelectric conversion element 1 according to this embodiment is a photoelectric conversion element 1 including the light absorption layer 4 which is provided on the lower electrode layer 3 and which is formed of a group I-III-VI compound containing a group I-B element, a group III-B element, and Se, and the semiconductor layer 5 which is provided on the light absorption layer 4 and which is formed of a group III-VI compound containing a group III-B element, S, and Se. In addition, the composition (atomic percent) of Se of the group III-VI compound of the semiconductor layer 5 is higher at the light absorption layer 4 side than that at the side opposite thereto.

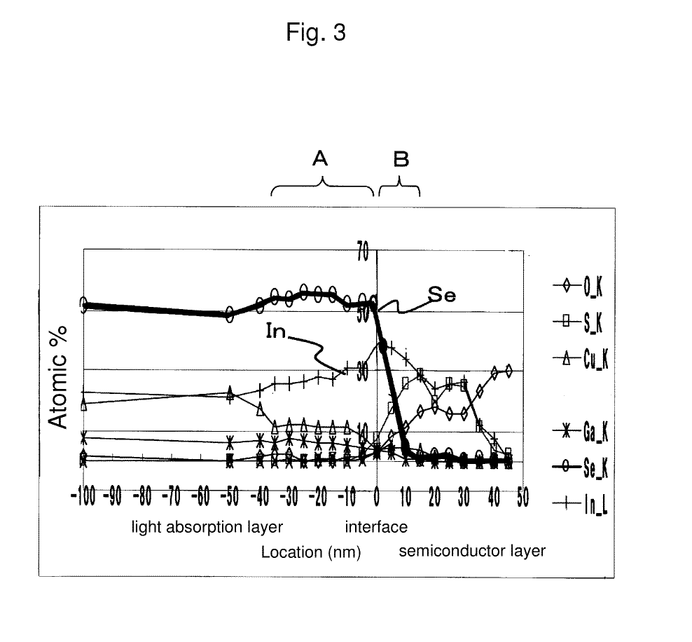

From the graph of a composition distribution of the photoelectric conversion element 1 according to this embodiment shown in FIG. 3, it is found that the composition of Se in the semiconductor layer 5 at the light absorption layer 4 side plotted by O is higher than that at the side opposite thereto.

In this case, the composition of Se at the light absorption layer 4 side is preferably 25 atomic percent or more in average in order to enable the band offset to have a positive value, and in addition, in order to enable the band offset to have a positive value, it is important that over a range (B range) of the semiconductor layer 5 from an interface 9 between the light absorption layer 4 and the semiconductor layer 5 to 10 nm or more apart therefrom, the composition of Se be set to be high.

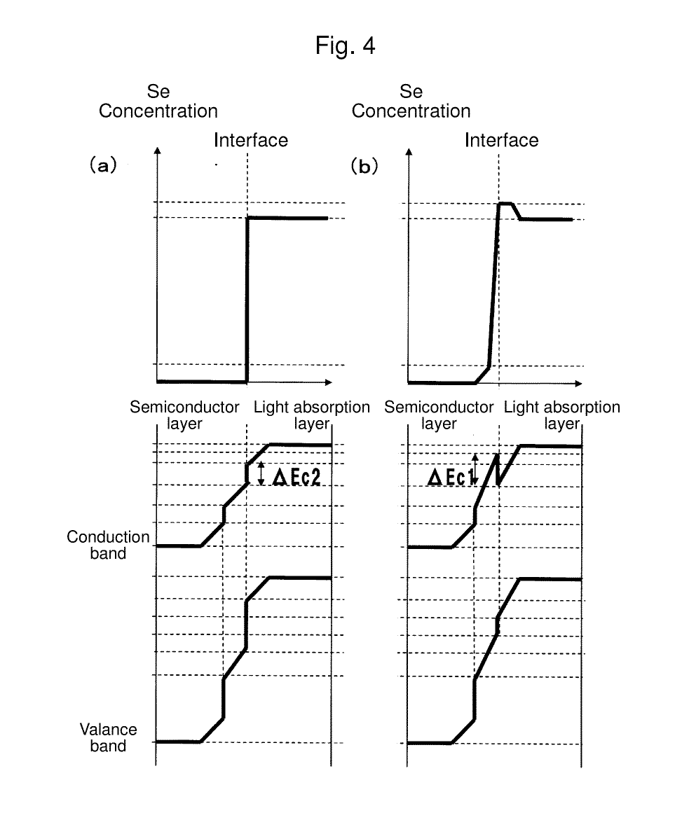

In the graphs in FIG. 4 each showing the relationship between the composition distribution of Se and the band offset, compared to a related example shown in FIG. 4(a) in which In₂S₃ is used for the semiconductor layer 5, when In₂Se₃ having a larger band offset is further contained as shown in FIG. 4(b) according to this embodiment, a band offset ΔEc2 having a negative value is changed to a band offset ΔEc1 having a positive value at the interface 9 between the light absorption layer 4 and the semiconductor layer 5. Hence, carrier recombination caused by crystalline defects is suppressed, and as a result, the photoelectric conversion efficiency can be improved.

That is, when the semiconductor layer 5 is formed of a laminate of In₂Se₃ and In₂S₃ or a mixture therebetween, while a low valence band level is maintained, a hole block effect can be maintained.

In order to obtain the tendency of the band offset as described above, the composition of Se is preferably monotonically decreased along a direction apart from the interface 9 between the light absorption layer 4 and the semiconductor layer 5.

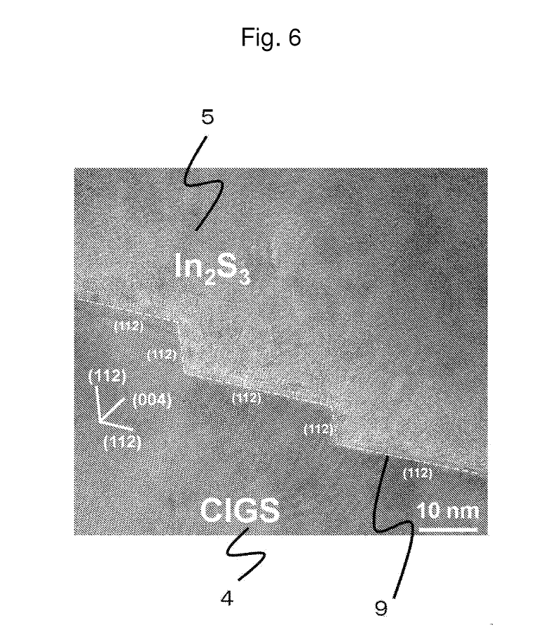

In this case, as shown in FIG. 6, in a TEM photo of a cross-section taken along a lamination direction of the light absorption layer 4 and the semiconductor layer 5, it can be observed that the orientation plane of the light absorption layer 4 is different from that of the semiconductor layer 5. The boundary between these different orientation planes is the interface 9 between the light absorption layer 4 and the semiconductor layer 5.

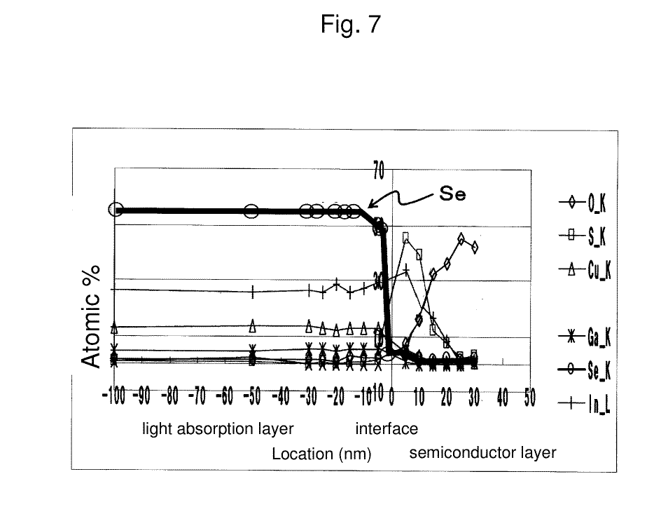

FIG. 7 is a graph showing the composition distribution of a related solar cell element 1, and at the interface 9, the composition distribution of S and that of O are preferable (S>O). However, since the composition (bold line) of Se is decreased at the interface 9 to a level similar to that of the semiconductor layer 5, the photoelectric conversion efficiency is decreased.

On the other hand, in this embodiment shown in FIG. 3, although it is not preferable since the composition distribution of S is not so much different from that of O at the interface 9, the composition distribution (bold line) of Se in the semiconductor layer 5 is higher at the light absorption layer 4 side than that at the side opposite thereto, and hence, the photoelectric conversion efficiency is increased.

Accordingly, it is found that, for example, compared to the composition distribution of S and that of O, the composition distribution of Se has a dominant influence on the photoelectric conversion efficiency.

Furthermore, in the photoelectric conversion element 1 according to this embodiment, the light absorption layer 4 preferably has a region 4a at a semiconductor layer 5 side in which the composition of Se is higher than that at a lower electrode layer 3 side. That is, as shown in FIG. 1, the region 4a is present at a side at which the light absorption layer 4 is in contact with the semiconductor layer 5.

For example, in the graph of the composition distribution of the photoelectric conversion element 1 according to this embodiment shown in FIG. 3, the composition (bold line) of Se in the light absorption layer 4 protrudes in the region 4a (range A) located in the vicinity of the interface 9.

In addition, in FIG. 3, although the whole composition distribution of the light absorption layer 4 is not shown, in the region other than the region 4a (range A), the protrusion of the composition of Se is not confirmed.

Accordingly, while the semiconductor layer 5 is being formed, Se can be made likely to dissolve out of the surface of the light absorption layer 4 into a precursor of the semiconductor layer 5.

Furthermore, after the semiconductor layer 5 is formed, Se is likely to diffuse out of the surface of the light absorption layer 4 into the semiconductor layer 5, and hence, O (oxygen), which is the same group VI element as Se, is suppressed from diffusing from the semiconductor layer 4 side to the vicinity of the interface 9, so that a preferable pn junction may be maintained.

In this case, the average composition of Se in the region 4a is preferably higher than the average composition of Se in the whole light absorption layer 4 by 5 atomic percent or more.

In addition, in FIG. 3, since the composition of In has the maximum value in the vicinity of the interface 9, the series resistance between the semiconductor layer 5 and the light absorption layer 4 can be decreased, and hence, the photoelectric conversion efficiency can be preferably increased.

Furthermore, in the photoelectric conversion element 1 according to this embodiment, the region 4a preferably has a higher composition of CuSe or CuSe₂ than that in any other portion of the light absorption layer 4.

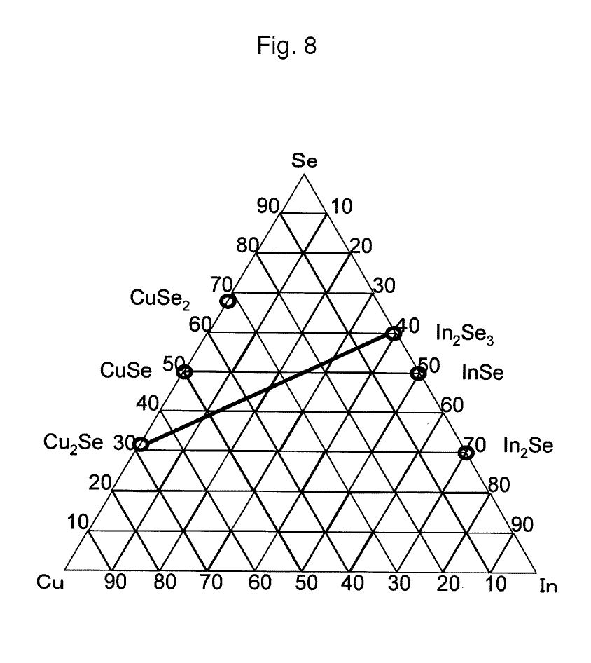

For example, Cu₂Se, CuIn₅Se₈, CuIn₃Se₅, Cu₂In₄Se₇, Cu₃In₅Se₉, and CuInSe₂, which are present on a liner line (bold line) connected between Cu₂Se and In₂Se₃ of a Cu—In—Se-based ternary phase diagram shown in FIG. 8, are stable Se compounds.

On the other hand, since CuSe or CuSe₂ is an unstable Se compound which easily dissolves out, Se is likely to dissolve out of the surface of the light absorption layer 4 into the semiconductor layer 5 while the semiconductor layer 5 is being formed, or after the semiconductor layer 5 is formed, Se can be made likely to diffuse into the semiconductor layer 5.

Furthermore, in the photoelectric conversion element 1 according to this embodiment, the region 4a is preferably a range from the interface 9 between the light absorption layer 4 and the semiconductor layer 5 to a position 10 nm apart therefrom˜to a position 50 nm apart therefrom.

For example, the range A in FIG. 3 corresponding to this range 4a is a range from the interface 9 to a position 40 nm apart therefrom, and the average composition of Se is 52 to 56 atomic percent.

In addition, in the semiconductor layer 5, the composition of Se tends to increase in a range from the interface 9 to a position 1 nm apart therefrom˜to a position 10 nm apart therefrom, and for example, in FIG. 3, in the range B (range from the interface 9 to a position 10 nm apart therefrom), the composition of Se increases.

Furthermore, in the photoelectric conversion element 1 according to this embodiment, the average composition of Se of the light absorption layer 4 is preferably in a range of 40 to 60 atomic percent, and the ratio (minimum composition of Se)/(maximum composition of Se) of the minimum composition of Se to the maximum composition of Se in the light absorption layer 4 is preferably 0.8 to 0.95.

Accordingly, while the semiconductor layer 5 is being formed, Se can be made likely to appropriately dissolve out of the surface of the light absorption layer 4 into the precursor of the semiconductor layer 5.

Furthermore, after the semiconductor layer 5 is formed, since Se is made likely to appropriately diffuse out of the surface of the light absorption layer 4 into the semiconductor layer 5, O (oxygen), which is the same group VI element as Se, can be suppressed from diffusing from the semiconductor layer 4 side to the vicinity of the interface 9, and as a result, a preferable pn junction can be maintained.

### Method for Manufacturing Photoelectric Conversion Element

In a method for manufacturing the photoelectric conversion element 1 according to this embodiment, the light absorption layer 4 of a group I-III-VI compound containing a group I-B element, a group III-B element, and Se is immersed in a film forming solution containing a group III-B element, S, and Se while the ratio of Se to S in the film forming solution is decreased, so that the semiconductor layer 5 of a group III-VI compound is formed on the light absorption layer 4.

First, after the film forming solution containing a group III-B element, S, and Se is prepared, the immersion of the light absorption layer 4 of a group I-III-VI compound containing a group I-B element, a group III-B element, and Se into the film forming solution is started.

In addition, to the film forming solution containing a group III-B element, S, and Se, a second film forming solution having a lower ratio of Se to S than that of the above film formation solution is appropriately added, so that the ratio of Se to S in the film forming solution is decreased.

Alternatively, after immersed in the second film forming solution having a lower ratio of Se to S than that of this film forming solution, the light absorption layer 4 is further immersed in a third film forming solution having a lower ratio of Se to S than that of the second film forming solution. The process as described above is repeatedly performed, so that the ratio of Se in the semiconductor layer 5 is decreased.

Accordingly, as shown in FIG. 3, the composition of Se of the group III-VI compound in the semiconductor layer 5 can be increased at the light absorption layer 4 side as compared to that at the side opposite thereto.

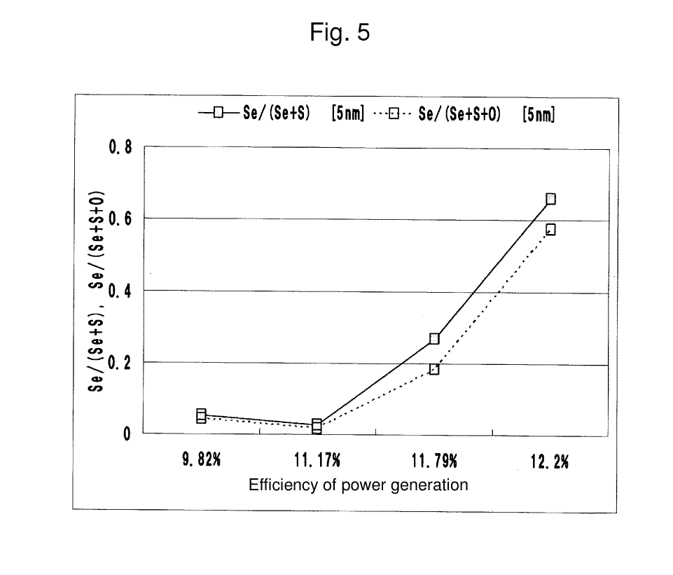

FIG. 5 is a graph showing the photoelectric conversion efficiency with respect to Se/(Se+S) or Se/(Se+S+O) of the semiconductor layer 5 at a position approximately 5 nm apart from the interface 9, and it is found that as Se/(Se+S) or Se/(Se+S+O) is increased, the conversion efficiency is improved.

That is, the ratio of the concentration of Se to the concentration of the all group VI-B elements may be controlled in a range, for example, of approximately 0.6 or more.

In addition, as apparent from FIG. 3, for example, at the interface 9, since the composition of Se is high, and the composition of S and that of O are low, the ratio, Se/(Se+S) or Se/(Se+S+O), is close to 1.

On the other hand, as the position in the semiconductor layer 5 is far from the interface 9, since the composition of Se is decreased, and the composition of S and that of O are increased, the ratio, Se/(Se+S) or Se/(Se+S+O), becomes closer to 0.

By the method for manufacturing the photoelectric conversion element 1 as described above, a desired photoelectric conversion 1 can be obtained.

Furthermore, when the following manufacturing is performed, the composition of Se in the region 4a can be increased, and the diffusion of Se from the light absorption layer 4 into the semiconductor layer 5 can be promoted.

That is, when the light absorption layer 4 is formed, in a temperature rise step of firing a film containing a group I-B element, a group III-B element, a group VI-B element on the lower electrode layer 3, a H₂Se gas is introduced after the temperature reaches a predetermined temperature.

When the timing of the introduction of an H₂Se gas is delayed in the firing of the light absorption layer 4 as described above, the composition of Se at the lower electrode layer 3 side of the light absorption layer 4 is decreased, and Se can be preferentially introduced into the region 4a.

In this case, since the composition of Se in the region 4a can be easily increased, the timing of the introduction of an H₂Se gas is preferably performed in a range of 400° C. to 450° C.

In addition, an H₂Se gas may also be introduced during the film formation for the light absorption layer 4.

### REFERENCE SIGNS LIST

1: photoelectric conversion element
2: substrate
3: lower electrode layer
4: light absorption layer
4a: region
5: semiconductor layer
7: upper electrode layer
8: grid electrode (collector electrode)
8a: finger electrode
8b: bus bar electrode
9: interface
10: photoelectric conversion device

1. A photoelectric conversion element, comprising:
a lower electrode layer;
a light absorption layer disposed on the lower electrode layer, and comprising a group compound containing a group I-B element, a group III-B element, and Se; and
a semiconductor layer disposed on the light absorption layer and comprising a group III-VI compound containing a group III-B element, S, and Se,
wherein the composition in atomic percent of Se of the group III-VI compound of the semiconductor layer at a side of the light absorption layer is higher than that at a side opposite to the light absorption layer.

2. The photoelectric conversion element according to claim 1, wherein the light absorption layer includes a region having a higher composition of Se at a side of the semiconductor layer than that at a side of the lower electrode layer.

3. The photoelectric conversion element according to claim 2, wherein a composition of CuSe or CuSe2 in the region is higher than that in any other portion of the light absorption layer.

4. The photoelectric conversion element according to claim 2, wherein the region is disposed at an interface between the light absorption layer and the semiconductor layer, and has a thickness of 10 nm to 50 nm.

5. The photoelectric conversion element according to claim 1, wherein
the average composition of Se in the light absorption layer is in a range of 40 to 60 atomic percent, and
the ratio of the minimum composition of Se in the light absorption layer to the maximum composition of Se therein is 0.8 to 0.95.

6. A method for manufacturing a photoelectric conversion element, the method comprising:
immersing a light absorption layer composed of a group I-III-VI compound containing a group I-B element, a group III-B element, and Se in a film forming solution containing a group III-B element, S, and Se; and
forming a semiconductor layer composed of a group III-VI compound on the light absorption layer while making the ratio of Se to S in the film forming solution lower.

7. A photoelectric conversion device, comprising the photoelectric conversion element according to claim 1.
